(19) United States
(12) Patent Application Publication
(10) Pub. No.: US 2018/0340658 A1
(43) Pub. Date: Nov. 29, 2018

(54) LED ILLUMINATING DEVICE

(71) Applicant: LEDVANCE GmbH, Garching bei Munchen (DE)

(72) Inventors: Jing Lin, Shenzhen, Guangdong (CN); Wei Xiong, Shenzhen, Guangdong (CN); Shijun Nie, Shenzhen, Guangdong (CN); Shaozhu Yang, Shenzhen, Guangdong (CN)

(21) Appl. No.: 15/757,749

(22) PCT Filed: Sep. 9, 2016
(86) PCT No.: PCT/EP2016/071283

§ 371 Date: Mar. 6, 2018

(30) Foreign Application Priority Data
Sep. 9, 2015 (CN) 201510572010.7

(51) Int. Cl. F21K 9/275; H01L 33/00

(52) U.S. Cl. CPC F21K 9/275; H01L 33/00

(57) ABSTRACT

An LED illuminating device (100), comprising a base (2), a bulb (3) mounted on the base (2), and a lighting module (1) received in the bulb (3), wherein the lighting module (1) comprises a first lighting assembly (11), the first lighting assembly (11) comprises a plurality of lighting bodies (111), wherein the first lighting bodies (111) have a linear shape and are configured to emit light in a direction away from an optical axis of the LED illuminating device (100), characterized in that the lighting module (1) further comprises a second lighting assembly (12), wherein the second lighting assembly (12) is configured to emit light at least in the direction of the optical axis.

### TECHNICAL FIELD

The present invention relates to an LED illuminating device.

### BACKGROUND ART

The LED illuminating device uses the LED illuminating technology, and has the advantages such as high efficiency, energy saving, and long service life. The existing LED illuminating devices can for example be designed with an outline of the conventional incandescent lamp, i.e., have a bulb with the same shape as that of the incandescent lamp, but the lighting device within the bulb is replaced by a light source using the LED technology. With the development of the LED technology, the LED filament starts to be used as the light source of the LED illuminating device, and this light source is also applied to the bulb with the same outline as the bulb of the conventional incandescent lamp so as to make the LED filament lamp. However, when the existing LED filament lamp is for example used as a pendant lamp to hang on the ceiling, the light intensity below the lamp is insufficient such that the light distribution of the exit light from the lamp is not uniform. Besides, as the power of the LED filament lamp is only focused on the filament, the filament of the lamp will always operate under high temperatures, as a result, the service life of the lamp will be reduced.

### SUMMARY OF THE INVENTION

In order to solve the above-mentioned technical problems, the present invention application provides a novel LED illuminating device. The LED illuminating device according to the present invention can allow the exit light to be more uniform, can improve the light efficiency of the illuminating device, and prolong the service life of the illuminating device.

The object of the present invention is achieved through such an LED illuminating device that comprises a base, a bulb mounted on the base, and a lighting module received in the bulb, wherein the lighting module comprises a first lighting assembly, the first lighting assembly comprises a plurality of lighting bodies, wherein the first lighting bodies have a linear shape and are configured to emit light in a direction away from an optical axis of the LED illuminating device, wherein the lighting module further comprises a second lighting assembly, wherein the second lighting assembly is configured to emit light at least in the direction of the optical axis.

With the application of the additional simple light-emitting structure, the LED illuminating device according to the present invention can improve and complement the light distribution of the lamp merely taking the LED filaments as the light source, and the light intensity of the illuminating device in the direction of optical axis is enhanced, such that the uniformity of the exit light from the illuminating device is improved. The additional light-emitting structure used also can disperse the power supplied by the power supply to the light source so that this power will not be focused only on the LED filaments, which effectively reduces the operation temperature of the LED filaments, and prolongs the service life of the illuminating device.

According to a preferred example of the present invention, the lighting module further comprises a support, wherein the first lighting assembly and the second lighting assembly are supported on the support. The support additionally also can be configured to be used as a passage for filling gas into the bulk when manufacturing the illuminating device, and used to support and maintain the first light-emitting assembly and the second light-emitting assembly. The support can be configured to be transparent such that the light distribution of the exit light from the illuminating device will not be apparently affected.

According to a preferred example of the present invention, the second lighting assembly is configured in a disk shape, and is fixed and supported at the end of the support which is away from the base. The disk-shaped second lighting assembly can be directly mounted on the support, and the first lighting assembly is electrically connected to the second lighting assembly.

According to another preferred example of the present invention, the second lighting assembly is configured in a ring shape, and is fixed and supported at the end of the support which is close to the base. The linear-shaped first lighting assembly can be directly mounted on the support at one end, and connected to the ring-shaped second lighting assembly at the other end.

According to a preferred example of the present invention, the first lighting bodies are configured as LED filaments, and the second lighting assembly is configured as an LED light engine. The LED filaments can provide illumination in the bulb at least in the circumferential direction of the illuminating device, and the LED light engine can provide illumination at least in the direction of the optical axis such that the LED light engine can complement and enhance the illuminating effect of the LED filaments. Besides, the light engine can meanwhile share the power supplied by the power source to the light source such that the power supply of the power source will not be focused only on the LED filaments.

According to a preferred example of the present invention, the second lighting assembly comprises LED chips mounted on a circuit board, wherein the LED chips are configured as top view LEDs. The top view LEDs, after mounted on the circuit board, can emit light in the direction of the normal of the circuit board, i.e., can emit light in the direction of the optical axis of the illuminating device.

### BRIEF DESCRIPTION OF THE DRAWINGS

The accompanying drawings constitute a part of the present description and are used to provide further understanding of the present invention. Such accompanying drawings illustrate the embodiments of the present invention and are used to describe the principles of the present invention together with the description. In the accompanying drawings the same components are represented by the same reference numbers. As shown in the drawings:

FIG. 1 shows a schematic diagram of an LED illuminating device according to a first example of the present invention;

FIG. 2 shows a schematic diagram of the LED illuminating device according to a second example of the present invention.

### DETAILED DESCRIPTION OF THE EMBODIMENTS

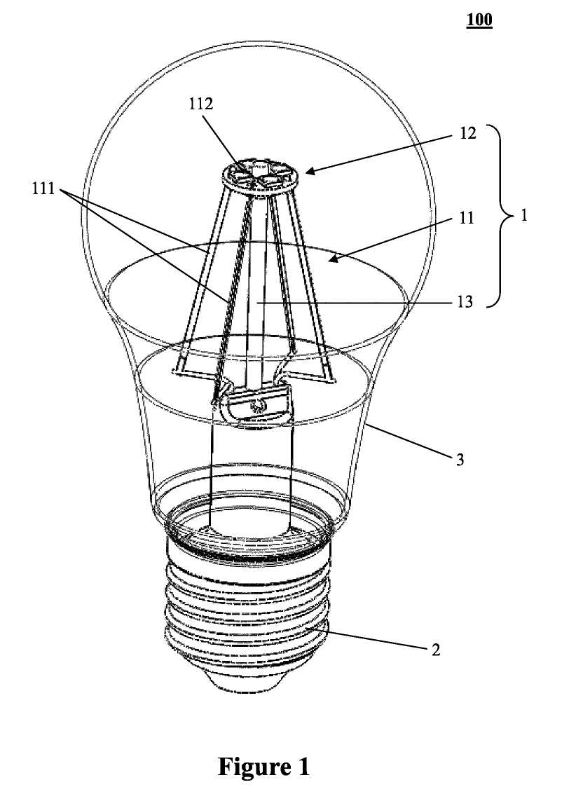

FIG. 1 shows a schematic diagram of an LED illuminating device 100 according to the first example of the present invention. The LED illuminating device 100 according to the present invention has an outline similar to that of the conventional incandescent lamp, and comprises a base 2, a bulb 3 mounted on the base 2, and a lighting module 1 mounted inside the bulb 3. The lighting module 1 of the LED illuminating device 100 according to the present invention comprises a first lighting assembly 11 and a second lighting assembly 12, and a support 13 for supporting the first lighting assembly 11 and the second lighting assembly 12, wherein the first lighting assembly 11 is configured to be constituted by a plurality of LED filaments as first lighting bodies 111, and the second lighting assembly 12 is configured to be constituted by an LED light engine. The LED light engine comprises top view LED chips as second lighting bodies 112 and a circuit board for carrying and driving the LED chips to emit light. The top view LED chips emit light in the direction of the normal of the circuit board of the light engine. The support 13 is arranged inside the bulb 3, and for example extends in the direction of the optical axis of the LED illuminating device 100.

In the first example according to the present invention, the LED light engine constituting the second lighting assembly 12 is configured as a disk-shaped circuit board, the LED chips are arranged on the disk-shaped circuit board which is arranged at one end of the support 13 away from the base 2. A perforation may be arranged in the center of the disk-shaped circuit board, and then the light engine is mounted and fixed on the support 13 by allowing the support 13 to pass through the perforation of the disk-shaped circuit board. Besides, the plurality of LED filaments constituting the first lighting assembly 11 can be connected electrically to the light engine at one end, and connected to the support 13 through conductors at the other end. Thus, the first lighting assembly 11 and the second lighting assembly 12 are supported on the support 13. In addition, the LED filaments can be mounted to incline and extend relative to the optical axis. Furthermore, the light engine and the LED filaments mounted on the support 13 jointly can share the power supply from the power source, for example, the top view LED chips occupy a quarter of the power of the total power supply, and the LED filaments occupy three quarters of the power of the total power supply. However, the proportions of power of the LED chips and of the LED filaments can be changed correspondingly according to the inclined angle of the LED filaments relative to the optical axis.

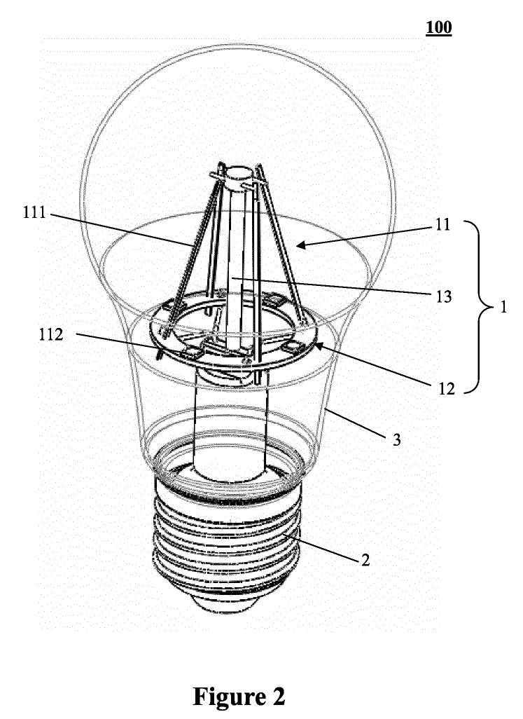

FIG. 2 shows a schematic diagram of the LED illuminating device 100 according to the second example of the present invention. The LED illuminating device 100 according to the second example of the present invention also comprises a base 2, a bulb 3 mounted on the base 2, and a lighting module 1 mounted inside the bulb 3. The lighting module 1 according to the second example also comprises a first lighting assembly 11 and a second lighting assembly 12, and a support 13 for supporting the first lighting assembly 11 and the second lighting assembly 12. However, different from the first example as described above, the second lighting assembly 12 according to the second example is configured with a ring shape, and a ring-shaped LED light engine therefore can be mounted and fixed at one end of the support 13 in the vicinity of the base 2, and first lighting bodies 111 constituting the first lighting assembly 11 are connected electrically to a circuit board of the LED light engine at one end, and connected to one end of the support 13 away from the base 2 at the other end. The LED chips of the LED light engine according to the second example are also designed as top view LEDs.

The above is merely preferred embodiments of the present invention but not to limit the present invention. For the person skilled in the art, the present invention may have various alterations and changes. Any alterations, equivalent substitutions, improvements, within the spirit and principle of the present invention, should be covered in the protection scope of the present invention.

### LIST OF REFERENCE SIGNS

1 lighting module
2 base
3 bulb
11 first lighting assembly
111 first lighting body
112 second lighting body
12 second lighting assembly
13 support
100 illuminating device

What is claimed is:

1. An LED illuminating device (100), comprising a base (2), a bulb (3) mounted on the base (2), and a lighting module (1) received in the bulb (3), wherein the lighting module (1) comprises a first lighting assembly (11), the first lighting assembly (11) comprises a plurality of lighting bodies (111), wherein the first lighting bodies (111) have a linear shape and are configured to emit light in a direction away from an optical axis of the LED illuminating device (100), characterized in that the lighting module (1) further comprises a second lighting assembly (12), wherein the second lighting assembly (12) is configured to emit light at least in the direction of the optical axis.

2. The LED illuminating device (100) according to claim 1, characterized in that the lighting module (1) further comprises a support (13), wherein the first lighting assembly (11) and the second lighting assembly (12) are supported on the support (13).

3. The LED illuminating device (100) according to claim 2, characterized in that the second lighting assembly (12) is configured in a disk shape, and is fixed and supported at the end of the support (13) which is away from the base (2).

4. The LED illuminating device (100) according to claim 2, characterized in that the second lighting assembly (12) is configured in a ring shape, and is fixed and supported at the end of the support (13) which is close to the base (2).

5. The LED illuminating device (100) according to claim 1, characterized in that the first lighting bodies (111) are configured as LED filaments, and the second lighting assembly (12) is configured as an LED light engine with a plurality of second lighting bodies (112).

6. The LED illuminating device (100) according to claim 1, characterized in that the second lighting assembly (12) comprises LED chips mounted on a circuit board, wherein the LED chips are configured as top view LEDs.
